(19) United States
(12) Patent Application Publication
(10) Pub. No.: US 2010/0259202 A1
(43) Pub. Date: Oct. 14, 2010

(54) APPARATUS FOR PRODUCING CONTINUOUS WAVEFORMS WITH PROGRAMMABLE SHAPES

(75) Inventor: THOMAS ALLEN KNOTTS, Mountain View, CA (US)

Correspondence Address: CONNOLLY BOVE LODGE & HUTZ LLP, P.O. BOX 2207, WILMINGTON, DE, 19899, US

(73) Assignee: MEDSOLVE TECHNOLOGIES, INC.

(21) Appl. No.: 12/788,466

(22) Filed: May 27, 2010

Related U.S. Application Data
(63) Continuation of application No. PCT/US2008/085012, filed on Nov. 26, 2008.
(60) Provisional application No. 60/991,143, filed on Nov. 29, 2007.

(51) Int. Cl. H01L 41/02

(52) U.S. Cl. 318/116

(57) ABSTRACT

Devices and methods are provided for boosting a battery voltage and driving an actuator with programmable voltage shapes. In one embodiment, there is provided a device (e.g., an actuator driver) that includes: a boost circuit coupled to the actuator and a battery; a switch driver coupled to the boost circuit; at least one current source coupled to the actuator; a switch-driver amplifier coupled to the switch driver and the at least one current source; and a microcontroller or an application specific integrated circuit (ASIC) coupled to and controlling the at least one current source to apply a shaped voltage to the actuator.

### CROSS-REFERENCE TO RELATED APPLICATION(S)

This application claims priority pursuant to 35 U.S.C. §119(e) to U.S. Provisional Application No. 60/991,143, filed Nov. 29, 2007, entitled “LOW-POWER, HIGH-VOLTAGE ACTUATOR DRIVER CIRCUIT THAT PRODUCES CONTINUOUS WAVEFORMS WITH PROGRAMMABLE SHAPES,” which application is specifically incorporated herein, in its entirety, by reference.

### BACKGROUND OF THE INVENTION

1. Field of the Invention

The present application relates generally to the delivery of therapeutic or diagnostic agents into a living body, and more specifically to apparatuses and methods for driving an actuator of an infusion pump.

2. Description of the Related Art

Some medical procedures and devices employ the infusion of therapeutic agents into living bodies over periods of time, and such procedures and devices have been used for the infusion of insulin or the like. One example of a device for the infusion of therapeutic or diagnostic agents being developed is an infusion pump. This pump is intended to be driven by a ceramic actuator. FIG. 1 shows an example actuator 100 that includes layered, disparate materials that use a linear differential expansion to cause the actuator bending, when a voltage is applied. When driven with positive or negative voltages, the actuators can be made to bend both up and/or down from nominal. For certain applications, such as infusion pumps that only require downward displacement, a single-ended drive voltage is applied, as shown in FIG. 1.

Development of such pumps and related components are part of an ongoing effort to improve techniques for infusing agents, such as, for example, those techniques and approaches described in U.S. patent application Ser. No. 11/548,238, filed Oct. 10, 2006, entitled “METHOD AND APPARATUS FOR INFUSING LIQUID TO A BODY.”

Exemplary actuator force-versus-displacement curves as a function of applied voltage are shown in FIG. 2. The electrical model of the actuator can be approximated as an ideal 2.4 μF capacitor. For example, when the actuator drive electronics are required to drive this capacitor from 0 to 60 volts, one of the main challenges may be to generate this high voltage smoothly, from a low supply voltage (e.g., 3 to 4.2 volts), while maintaining a low per-cycle supply current to support a defined number of strokes (e.g., 6000 strokes) on a single battery charge. To operate such a pump, the actuator would preferably smoothly deflect down in 1-2 seconds, hold its position for ˜1 second, and then smoothly return to nominal, as shown in the two exemplary actuator voltage waveforms of FIG. 3. To accommodate different stroke shapes a flexible circuit solution with a programmable drive shape is needed. Accordingly, as shown in FIG. 4, it would be desirable to provide a technique for driving an actuator with a voltage, such as V_{c}, with smooth and controllable shapes, when powered with a battery or other power supply with a much smaller voltage, such as V_{B}, wherein V_{B}<<V_{c}, in a power-efficient way.

### SUMMARY OF THE INVENTION

Before proceeding to the detailed description of embodiments of the invention, a brief summary of the invention is provided as follows. The present invention relates to electrical circuits for driving an actuator in an infusion pump, or other devices that demand (a) the efficient use of battery power and (b) smooth and controllable voltages shapes be provided to the actuator. With respect to the demand for (b), in the illustrative context of an actuator inside an insulin pump, it is important to provide an actuator voltage that causes the insulin pump to infuse insulin in a smooth and controllable manner, such that the desired dosage of the insulin is infused into the patient at a desired rate. If too little or too much insulin is delivered too quickly or too slowly, the results will not be as effective.

The present invention provides an apparatus/circuit for driving an actuator with programmable voltage shapes. The apparatus may comprise a battery for powering the actuator and a boost circuit coupled to the battery. The boost circuit may include an inductive element coupled to the battery, and a switch coupled to the inductive element and controlling an inductive current through the inductive element to generate a voltage gain, and thereby boost a battery voltage. The apparatus may further comprise at least one current source coupled to the boost circuit and the actuator, wherein the at least one current source includes: (a) a first current source having a first top node; and (b) a second current source having a second top node, the actuator being connected between the first and second top nodes. The apparatus may further comprise: a microcontroller or an application specific integrated circuit (ASIC) coupled to and controlling the at least one current source to apply a shaped boosted voltage to the actuator; a comparator coupled to the at least one current source; and a switch driver coupled to a comparator output of the comparator and to the switch of the boost circuit. The comparator preferably uses a current source voltage across at least one of the first and second current sources to control the boost circuit.

In a related aspect of the present invention, at least one of the first and second current sources is referenced to ground, and/or the comparator is referenced to ground.

In another related aspect of the present invention, the comparator is coupled to a reference voltage.

In another related aspect of the present invention, the actuator is connected between the boost circuit and at least one of the first and second top nodes.

In another related aspect of the present invention, an actuator voltage across the actuator is the difference between a first node voltage at the first top node and a second node voltage at the second top node. The apparatus may further comprise an actuator voltage sensing unit that provides a feedback signal to the microcontroller or ASIC, wherein the microcontroller or ASIC controls at least one of the first and second current sources based at least in part on the feedback signal.

In another related aspect of the present invention, at least one of the first and second current sources includes: a digital-to-analog converting device (DAC); an operational amplifier coupled to the DAC; a transistor coupled to the operational amplifier; and a resistor coupled to the amplifier and the transistor.

In yet another related aspect of the present invention, the above-described components of the apparatus for driving an actuator with programmable voltage shapes (e.g., the first and second current sources, the microcontroller, the comparator, the switch driver, etc.) may comprise circuits with further subcomponents.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 illustrates an actuator bending with single-ended drive.

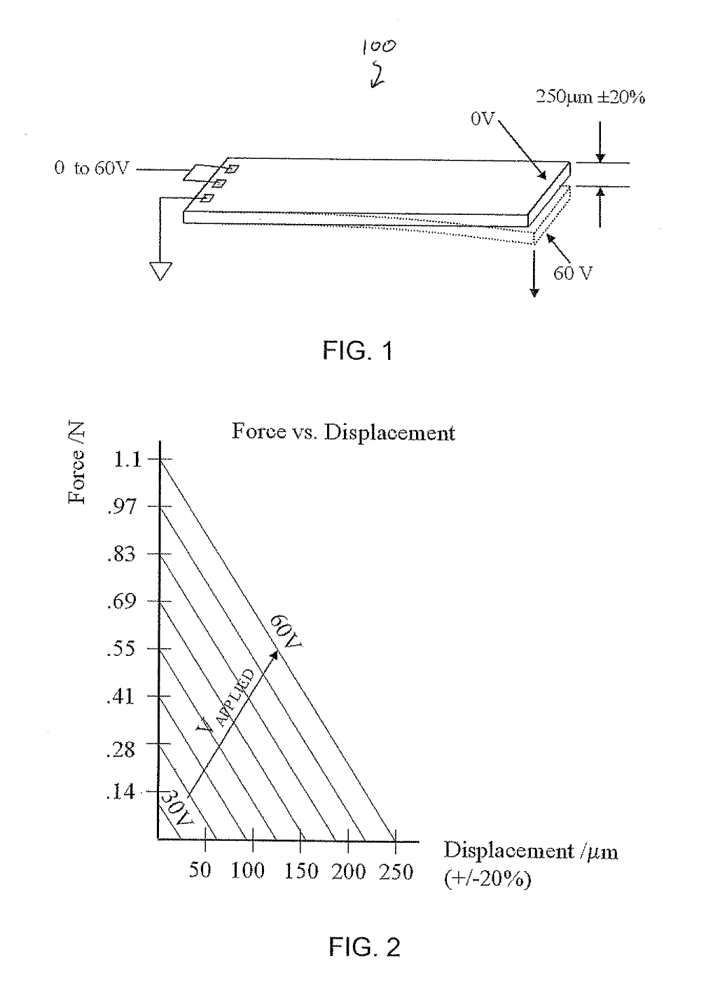

FIG. 2 shows Force vs. Displacement curves for an exemplary actuator.

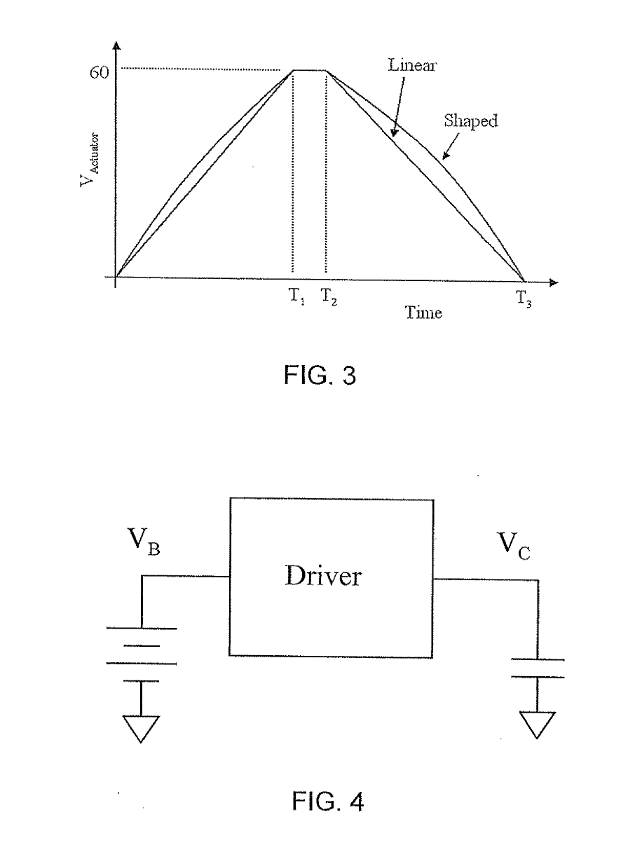

FIG. 3 depicts exemplary actuator voltage waveforms.

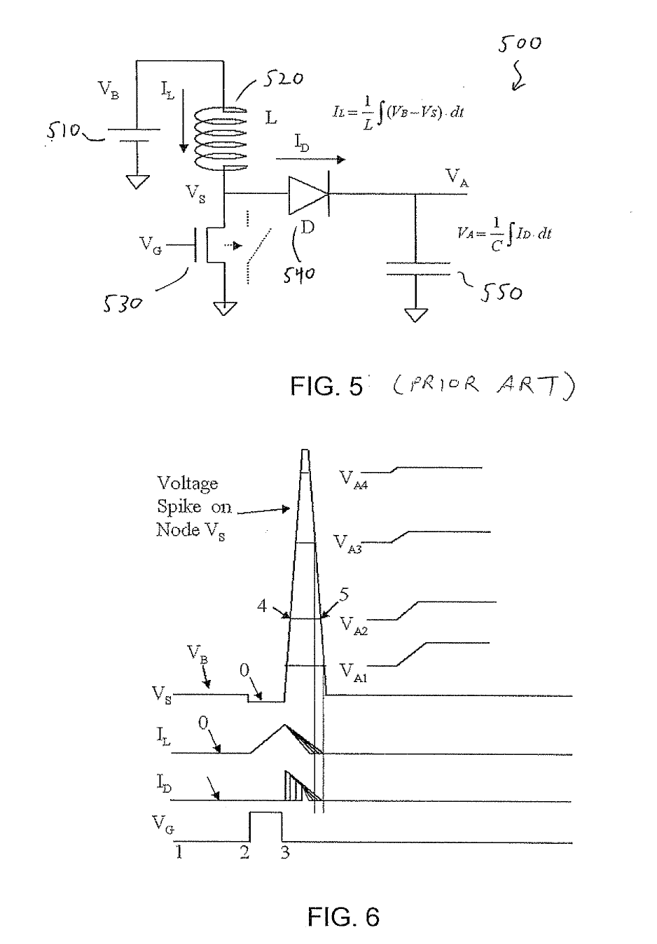

FIG. 4 shows an exemplary actuator driver.

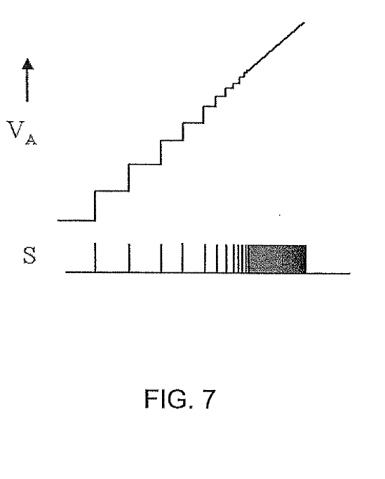

FIG. 5 illustrates an exemplary boost circuit.

FIG. 6 depicts various waveforms associated with the boost circuit of FIG. 5.

FIG. 7 illustrates the non-uniformly-spaced switch drive needed to generate a linear voltage ramp.

FIG. 8A shows an exemplary actuator driver with dual programmable current sources.

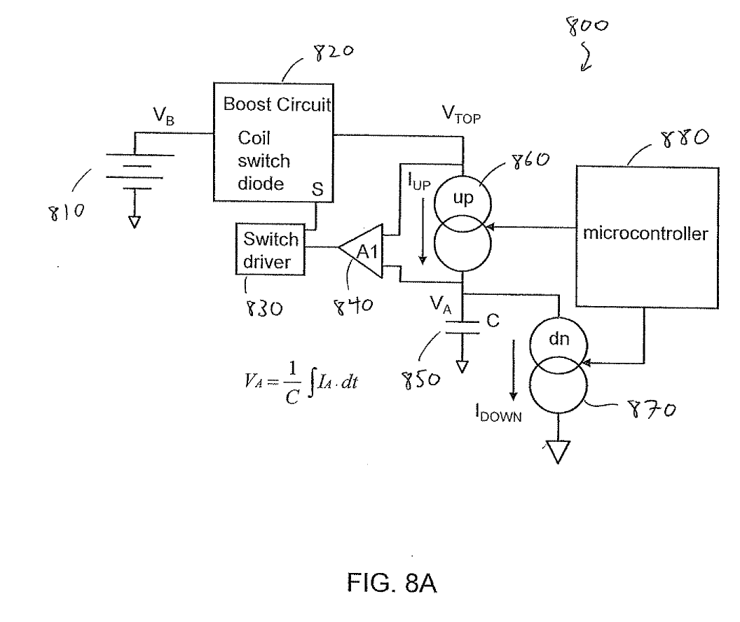

FIG. 5B shows an exemplary current source.

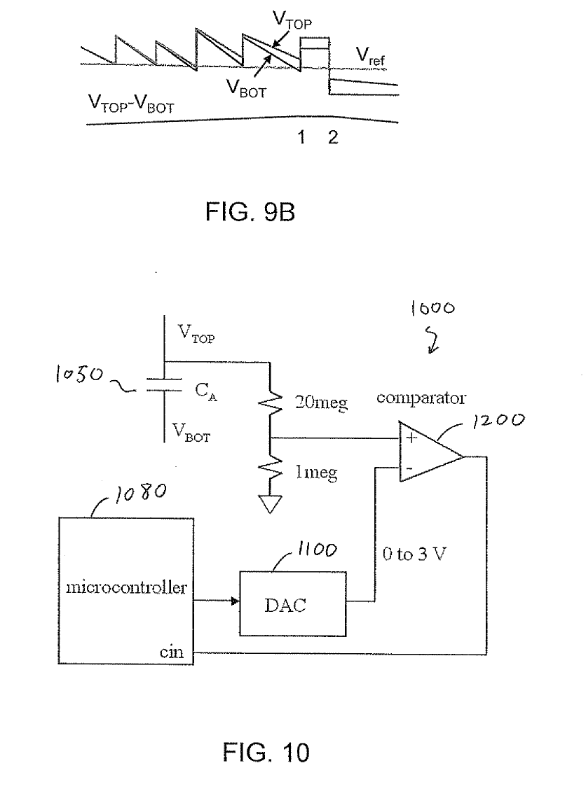

FIG. 8C depicts exemplary waveforms that be generated with the actuator driver of FIG. 8A.

FIG. 9A illustrates one embodiment of a circuit topology for an actuator driver.

FIG. 9B depicts voltage waveforms associated with the actuator driver of FIG. 9A.

FIG. 10 shows an exemplary circuit for detecting a V_{TOP} threshold.

### DETAILED DESCRIPTION

Various embodiments are now described with reference to the drawings, wherein like reference numerals are used to refer to like elements throughout. In the following description, for purposes of explanation, numerous specific details are set forth in order to provide a thorough understanding of one or more embodiments. It may be evident, however, that such embodiment(s) can be practiced without these specific details. In other instances, well-known structures and devices are shown in block diagram form in order to facilitate describing one or more embodiments.

In accordance with one or more embodiments and corresponding disclosure thereof, various aspects are described in connection with a driver circuit (e.g., for an infusion pump or the like) that (a) boosts the battery voltage, and (b) controls the shape of the boosted voltage. For example, in one scenario for driving an actuator with a voltage, such as V_{C}, when powered with a battery or other power supply with a much smaller voltage, such as V_{B}, wherein V_{B}<<V_{C}, it would be desirable to boost V_{B} in a power-efficient way.

With reference to FIG. 5, a known approach to voltage boosting might include implementing a boost circuit 500 that boosts V_{B} 512 of battery 510, and that may include a coil (inductor) 520, switch (a FET is an ideal choice) 530, and a diode 540 that is coupled to the actuator 550. The voltage across the actuator 550 is represented as V_{A} 552, which is equal to the equation shown in FIG. 5.

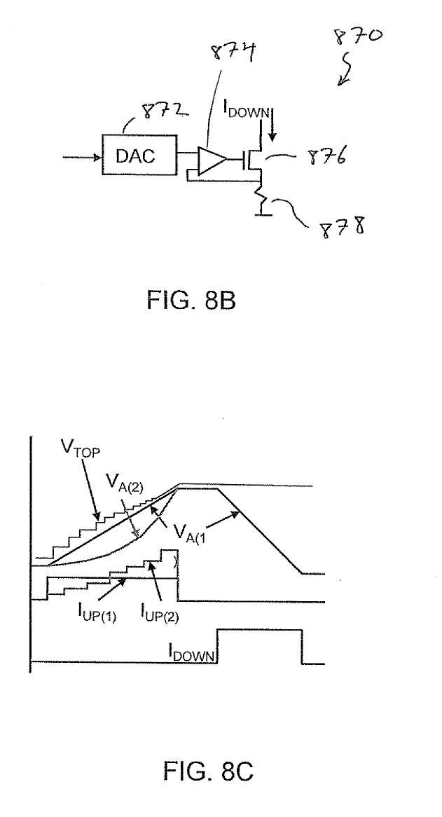

FIG. 6 illustrates various waveforms associated with boost circuit 500 of FIG. 5. Initially (point 1), the switch 530 is off, and the voltage across inductor 520 and the current I_{L} through the inductor 520 are zero. At point 2 on the waveform, the switch 530 closes, the voltage Vₛ is driven to zero, and the battery voltage V_{B} is applied across the inductor 520. This causes the current I_{L} through the inductor 520 to increase linearly. At point 3, the switch 530 opens. Like a spinning flywheel, current I_{L} through inductor 520 cannot change instantaneously. It continues to flow into the high impedance of the off-switch causing a rapid spike in voltage V_{S} at the node where the inductor 520, switch 530, and diode 540 are coupled to each other. The voltage V_{S} climbs until it reaches whatever voltage is on the actuator 550 and the diode 550 turns on, at point 4. The inductor current I_{L} flows through the diode 550 and into the actuator 550, causing the actuator voltage V_{A} to climb. The inductor current I_{L} is now decreasing since the inductor 520 has a large negative bias. The inductor current I_{L} reaches zero and then starts to go negative. As this current tries to flow backwards through the diode 550, the voltage Vₛ starts to drop at point 5 and then rapidly returns to zero. Since the diode 550 is now off, the new higher actuator voltage V_{A} remains on the actuator 550 (with ideal components, this voltage would remain indefinitely, but due to a small reverse leakage current through the diode, the actuator voltage V_{A} 552 will slowly decay).

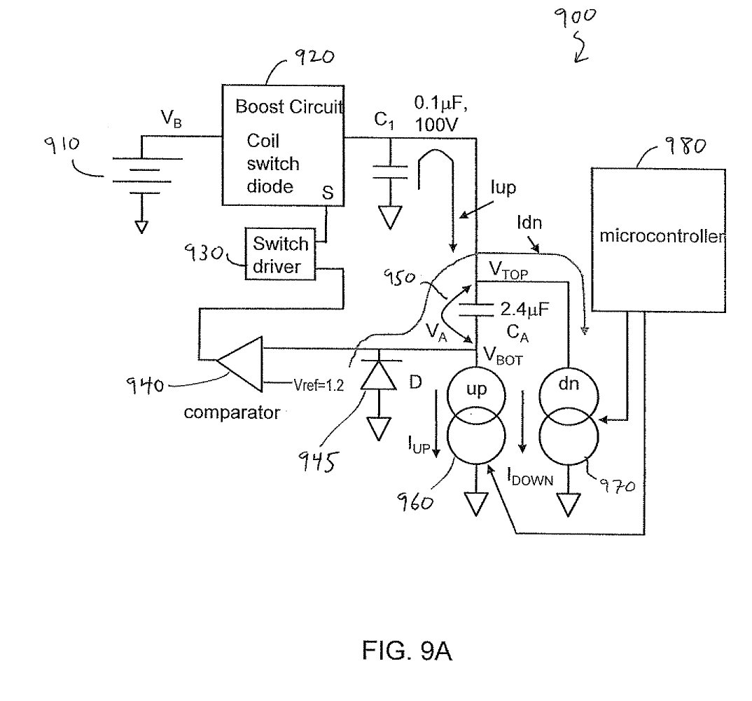

The higher the actuator voltage V_{A}, the longer it takes before the diode 540 turns on, the less inductor current I_{L} flows into the actuator 550, and the smaller the resulting step in actuator voltage V_{A}. This is depicted for four actuator voltages, V_{A1} to V_{A4} in FIG. 6. In order to generate a linear voltage ramp across the actuator, the switch rate must therefore increase as the actuator voltage V_{A} increases, as illustrated in FIG. 7.

It is noted that driving the actuator 550 directly via the circuit design of FIG. 5 can cause fast voltage steps. This will result in step impulses applied to the pump, and rapid field changes within the actuator 550 that will generate sonic emissions, and could adversely affect pumping. Accordingly, one approach to addressing problems associated with fast voltage steps might include implementing the circuit design of FIG. 8A. In FIG. 8A, there is provided an actuator driver 800 wherein the actuator capacitor C of actuator 850 is driven with current sources 860, 870. This is an ideal way to charge the capacitor C, since the resulting voltage V_{A} is a simple integral of the applied current I_{A}. Two programmable current sources 870 (for I_{DOWN}) and 860 (for I_{UP}) may be used. One approach to providing a current source might include implementing a current source 870 that includes a digital-to-analog converting device (DAC) 872, an operational amplifier 874, a transistor 876, and a resistor 878, as shown in the circuit design of FIG. 8B. Similarly, current source 860 may include the same components as current source 870, plus two additional transistors and resisters to mirror the current to feed it from above.

To generate a linear ramp waveform V_{A1}, such as the one illustrated in FIG. 8C, the microcontroller 880 may program the internal DAC of current source 860 for I_{UP} to have a fixed value and hold it there until the final voltage is reached and it turns off. To bring the waveform back down, the DAC may program current source 870 for I_{DOWN} in a similar manner. To generate the shaped waveform V_{A2}, the current source values may be changed on-the-fly. The resulting voltage waveform is continuous and without steps. In order for this circuit 800 to work, voltage V_{TOP} must be higher than voltage V_{A}, or the upper current source will stop functioning. This is achieved by connecting the boost circuit 820 to the node V_{TOP}. The amplifier A1 840 senses the voltage across the current source, and when necessary, the switch driver 830 turns the FET switch on and then off in the boost circuit to step up the voltage V_{TOP}. An advantage of this topology is that the voltage steps from the boost circuit 820 are mostly absorbed by the upper current source because of its high impedance, and is therefore nearly fully isolated from the actuator 850.

It is noted that the two additional mirror transistors (e.g., 60-V tolerant mirror transistors) of current source 860 can consume board area because they cannot be put into an ASIC, discussed in further detail below. It is also noted that amplifier A1 cannot be implemented directly due to the high voltage at its input, so resistor voltage-divider circuits are needed from V_{TOP}. To address such potential disadvantages with such circuit designs, there is provided an improved circuit topology for an actuator driver, illustrated in FIG. 9A. Specifically, the actuator driver 900 of FIG. 9A includes current sources 960, 970 and a switch-driver amplifier 940 (e.g., a single-ended comparator or the like), each of which are now referenced to ground. An actuator 950 is connected between the output of a boost circuit 920 and the top of the two current sources 960, 970. The actuator voltage V_{A} is the difference between the two node voltages V_{TOP} and V_{BOT}. To drive up the actuator voltage V_{A}, a microcontroller 980 turns on current source 960 (for I_{UP}). Since this current flows through the actuator from top to bottom, the actuator capacitor voltage increases. As shown in FIG. 9B, this current also flows through a filter capacitor C₁, which causes the voltage V_{TOP} to drop by the rate: ΔV_{Top}/ΔT=I_{UP}/C₁, referred to herein as equation 1. The actuator voltage V_{A} increases by the much slower rate: ΔV_{A}/ΔT=I_{UP}/C_{A}, referred to herein as equation 2.

It is noted that V_{Top} is drops because of the current from C₁, and that V_{BOT} drops because this current goes through C_{A}. As V_{Top} is dropping, it is also pulling V_{BOT} down. When V_{BOT} is too low and drops below a defined bottom limit (e.g., 1.2 volts), the comparator 940 keeps the current source active by triggering the boost circuit 920, which injects a pulse of current from its output as described earlier. This current flows mostly into C₁, since the impedance at V_{BOT} is very high compared to the impedance of C_{I}. The result is a very small and equal-sized step to V_{TOP} and V_{BOT}. This is important, because if the steps are equal, then the step is common mode to actuator 950 and actuator 950 will experience no step in voltage from boost circuit 920. The process repeats as shown in the FIG. 9B. As the actuator capacitor charges C_{A}, the difference between V_{TOP} and V_{BOT} gradually separate at the rate given in equation 3, described below. When the actuator voltage V_{A} reaches the programmable threshold, microcontroller 980 simply turns off the current I_{UP} at point 1, as illustrated in FIG. 9B. When it is time to bring the voltage back down, microcontroller 980 turns on the current I_{DN} at point 2. I_{DN} flows through the actuator 950 in the reverse direction, from the ground through diode D 945, as shown in FIG. 9A. This causes a rapid common mode drop of voltage of 1.2 plus the diode forward voltage, or about 2 V, to both V_{TOP} and V_{BOT}, and V_{BOT} then becomes clamped at −V_{D}. The voltage at V_{TOP} now drops at the rate of: ΔV_{TOP}/ΔT=I_{DN}/(C₁+C_{A}), referred to herein as equation 3.

In this example, the result is an approximately linear voltage ramp up and down, with programmable slopes. As discussed earlier, currents can be changed “on-the-fly” by microcontroller 980 (during the actuator motion) to produce a shaped voltage waveform rather than a linear one, if required or desired. Since the output voltage is produced from the integral of applied current, the voltage waveform is continuous when a change is made to the current. The voltage steps shown in FIG. 7 are not generated.

In related aspects, with reference to circuit component shown in FIG. 10, there is provided an actuator voltage sensor circuit 1000. With use of circuit 1000, the high voltages of the actuator 1050 is scaled to the non-boosted microcontroller supply, and the microcontroller 1080 can determine when the actuator voltage V_{TOP} has crossed a threshold going either up or down. For example, when driving the actuator voltage up to 60V (V_{TOP}=61.2V), the DAC 1100 is set to 2.9 V at its output and the microcontroller 1080 is signaled by a low-high transition from the comparator 1200 to indicate that the actuator voltage has reached this value. Similarly, this voltage output can be monitored on the way down, by looking for a high-low transition.

Actuator contact sensors or the like may be employed to provide electrical feedback when the actuator 1050 has fully flexed down and when it has returned back to the starting position. These signals may be used to stop the actuator motion. The circuit 1000 illustrated in FIG. 10 will thus not be used to start and stop the actuator motion, but instead will flag when the actuator voltage has traveled beyond its expected boundary indicating a possible stall of the actuator 1050. This circuit 1000 may also be needed when a shaped output is desired. The DAC 1100 may be set to indicate when the actuator voltage has reached some intermediate value, at which time the microcontroller 1080 can change the charge current, and set the DAC 1100 to the next intermediate value. In this way, a piecewise-linear voltage waveform can be generated with any desired shape, both going up and coming down.

In accordance with one or more aspects of the embodiments described herein, there is provided an apparatus/circuit for driving an actuator with programmable voltage shapes. For example, with reference to the embodiment of FIG. 9, the apparatus 900 may comprise a battery 910 for powering the actuator 950 and a boost circuit 920 coupled to the battery 910. The boost circuit 920 may include an inductive element coupled to the battery, and a switch coupled to the inductive element and controlling an inductive current through the inductive element to generate a voltage gain, and thereby boost a battery voltage. The apparatus 900 may further comprise at least one current source coupled to the boost circuit and the actuator, wherein the at least one current source includes: (a) a first current source 960 having a first top node; and (b) a second current source 970 having a second top node, the actuator 950 being connected between the first and second top nodes. The apparatus 900 may further comprise: a microcontroller 980 coupled to and controlling the at least one current source to apply a shaped boosted voltage to the actuator 950; a comparator 940 coupled to the at least one current source; and a switch driver 930 coupled to a comparator output of the comparator 940 and to the switch of the boost circuit 920. The comparator 940 preferably uses a current source voltage across at least one of the first and second current sources 960, 970 to control the boost circuit 920.

In related aspects, at least one of the first and second current sources 960, 970 is referenced to ground, and/or the comparator 940 is referenced to ground. In further related aspects, the comparator 940 is coupled to a reference voltage (e.g., 1.2 volts). In yet further related aspects, the actuator 950 is connected between the boost circuit 920 and at least one of the first and second top nodes.

In other related aspects, an actuator voltage across the actuator 950 is the difference between a first node voltage at the first top node and a second node voltage at the second top node. The apparatus 900 may further comprise an actuator voltage sensing unit that provides a feedback signal to the microcontroller 980, wherein the microcontroller 980 controls at least one of the first and second current sources 960, 970 based at least in part on the feedback signal.

In further related aspects, at least one of the first and second current sources 960, 970 includes: a digital-to-analog converting device (DAC); an operational amplifier coupled to the DAC; a transistor (e.g., field-effect transistor (FET), bipolar transistor, etc.) coupled to the operational amplifier; and a resistor coupled to the amplifier and the transistor.

In yet further related aspects, the above-described components of the apparatus for driving an actuator with programmable voltage shapes (e.g., the first and second current sources, the microcontroller, the comparator, the switch driver, etc.) may comprise a circuit with further subcomponents.

In accordance with one or more aspects of the embodiments described herein, there is provided an apparatus/circuit for sensing or monitoring the actuator voltage V_{A}. With reference to the embodiment of FIG. 10, the actuator driver may include or otherwise be coupled to an actuator voltage sensing unit/circuit 1000 that provides a feedback signal to the microcontroller 1080. The microcontroller 1080 may control the at least one current source (e.g., 960 and/or 970 in FIG. 9) based at least in part on the feedback signal.

In accordance with one or more aspects of the embodiments described herein, there is provided an apparatus/circuit for boosting the battery voltage V_{B}. The actuator driver may include or otherwise be coupled to a boost circuit that includes: an inductive element coupled to the battery; a switch (e.g., a transistor) coupled to the inductive element; and a diode coupled to the inductive element, the switch, and the actuator. The switch may control an inductive current through the inductive element to generate a voltage gain, and thereby boost the battery voltage V_{B}.

In accordance with one or more aspects of the embodiments described herein, there is provided an apparatus/circuit for providing at least one current (e.g., I_{UP} and/or I_{DOWN}). The actuator driver may include or otherwise be coupled to a current source that includes: a digital-to-analog converting device (DAC); an operational amplifier coupled to the DAC; a switch (e.g., a transistor) coupled to the operational amplifier; and a resistor coupled to the operational amplifier and the switch. In related aspects, the current source may also include a current mirror. The current mirror may include a combination of transistor and/or resistor, such as, for example, two transistors and two resistors.

In accordance with one or more aspects of the embodiments described herein, there is provided a method of providing a voltage to an actuator that involves controlling a current source to set the voltage applied to the actuator. For example, controlling the current source may comprise controlling two current sources. Controlling the current source may comprise using one current source to increase the voltage applied to the actuator, and a second current source to decrease the voltage applied to the actuator.

In related aspects, the method may include: monitoring the voltage across a current source; and controlling a boost circuit using the monitored voltage to set the voltage at a current source terminal. Controlling the current source may comprise using a programmed microcontroller. In further related aspects, the method may include: shaping the voltage applied to the actuator with a current source, wherein a programmed microcontroller is used control the shape of the voltage applied to the actuator.

In yet further related aspects, the method may include: monitoring the voltage across the actuator to provide a feedback signal; and controlling the current source using the feedback signal. In other related aspects, the method may include shaping the voltage applied to the actuator using the feedback signal, wherein a programmed microcontroller uses the feedback signal to control the shape of the voltage applied to the actuator.

One of ordinary skill in the art would understand that many of the discrete components described herein may be implemented in one or more application specific integrated circuits (ASICs). One of ordinary skill in the art also would understand that an ASIC could perform several, most or all of the tasks of the microcontroller. Such an implementation could be controlled by an external microcontroller or the like.

Furthermore, one of ordinary skill in the art would understand that a microcontroller and its functions may be implemented within one or more ASICs, digital signal processors (DSPs), digital signal processing devices (DSPDs), programmable logic devices (PLDs), field programmable gate arrays (FPGAs), processors, controllers, microcontrollers, microprocessors, electronic devices, other electronic units designed to perform the functions described herein, or a combination thereof.

While the present invention has been illustrated and described with particularity in terms of preferred embodiments, it should be understood that no limitation of the scope of the invention is intended thereby. Features of any of the foregoing methods and devices may be substituted or added into the others, as will be apparent to those of skill in the art. It should also be understood that variations of the particular embodiments described herein incorporating the principles of the present invention will occur to those of ordinary skill in the art and yet be within the scope of the invention.

1. An apparatus for driving an actuator with programmable voltage shapes, comprising:
a battery for powering the actuator;
a boost circuit coupled to the battery, the boost circuit comprising:
(a) an inductive element coupled to the battery; and
(b) a switch coupled to the inductive element and controlling an inductive current through the inductive element to generate a voltage gain, and thereby boost a battery voltage;
at least one current source coupled to the boost circuit and the actuator, the at least one current source comprising:
(a) a first current source having a first top node; and
(b) a second current source having a second top node, the actuator being connected between the first and second top nodes;
a microcontroller coupled to and controlling the at least one current source to apply a shaped boosted voltage to the actuator;
a comparator coupled to the at least one current source; and
a switch driver coupled to a comparator output of the comparator and to the switch of the boost circuit;
wherein the comparator uses a current source voltage across at least one of the first and second current sources to control the boost circuit.

2. The apparatus of claim 1, wherein at least one of the first and second current sources is referenced to ground.

3. The apparatus of claim 1, wherein the comparator is referenced to ground.

4. The apparatus of claim 1, wherein the comparator is coupled to a reference voltage.

5. The apparatus of claim 1, wherein the actuator is connected between the boost circuit and at least one of the first and second top nodes.

6. The apparatus of claim 1, wherein an actuator voltage across the actuator is the difference between a first node voltage at the first top node and a second node voltage at the second top node.

7. The apparatus of claim 6, further comprising an actuator voltage sensing unit that provides a feedback signal to the microcontroller, wherein the microcontroller controls at least one of the first and second current sources based at least in part on the feedback signal.

8. The apparatus of claim 1, wherein at least one of the first and second current sources comprises:
a digital-to-analog converting device (DAC);
an operational amplifier coupled to the DAC;
a transistor coupled to the operational amplifier; and
a resistor coupled to the amplifier and the transistor.

9. A system for driving an actuator with programmable voltage shapes, comprising:
a boost circuit, comprising:
(a) an inductive element coupled to a battery;
(b) a switch coupled to the inductive element and controlling an inductive current through the inductive element to generate a voltage gain, and thereby boost a battery voltage;
a current-source circuit coupled to the actuator, the current-source circuit comprising:
(a) a first current source configured to increase the boosted voltage, the first current source having a first top node;
(b) a second current source configured to decrease the boosted voltage, the second current source having a second top node;
an application specific integrated circuit (ASIC) coupled to and controlling the current-source circuit to apply a shaped boosted voltage to the actuator;
a comparator circuit coupled to the current-source circuit; and
a switch-driver circuit coupled to a comparator output of the comparator circuit and the switch of the boost circuit;
wherein the actuator is connected between the first and second top nodes;
wherein an actuator voltage across the actuator is the difference between a first node voltage at the first top node and a second node voltage at the second top node; and
wherein the comparator circuit uses a current source voltage across at least one of the first and second current sources to control the boost circuit via the switch-driver circuit.

10. The apparatus of claim 9, further comprising an actuator voltage sensing unit that provides a feedback signal to the ASIC, wherein the ASIC controls at least one of the first and second current sources based at least in part on the feedback signal.
